(19) United States
(12) Patent Application Publication
(10) Pub. No.: US 2011/0045673 A1
(43) Pub. Date: Feb. 24, 2011

(54) METHOD FOR MANUFACTURING A SILICON SURFACE WITH PYRAMIDAL TEXTURE

(75) Inventors: Juergen Schweckendiek, Berlin (DE); Ahmed Abdelbar Eljaouhari, Neunkirchen am Brand (DE)

Correspondence Address: KANESAKA BERNER AND PARTNERS LLP, 1700 DIAGONAL RD, SUITE 310, ALEXANDRIA, VA, 22314-2848, US

(73) Assignee: Rena GmbH, Guetenbach (DE)

(21) Appl. No.: 12/736,026

(22) PCT Filed: Mar. 12, 2009
(86) PCT No.: PCT/EP2009/001784

§ 371 Date: Oct. 28, 2010

(30) Foreign Application Priority Data
Mar. 14, 2008 (DE) 10 2008 014 166.6

(51) Int. Cl. H01L 21/306

(52) U.S. Cl. 438/747; 257/E21.219

(57) ABSTRACT

The invention relates to a method for manufacturing a silicon surface with a pyramidal structure, in which a silicon wafer containing the silicon surface is dipped into an etching solution. To produce a pyramidal structure that is as homogeneous as possible, according to the invention it is proposed that the silicon surface be treated with ozone prior to coming into contact with the etching solution.

The invention relates to a method for manufacturing a silicon surface with pyramidal texture as defined by the preamble of claim 1.

Such a method is known from EP 0 944 114 B1, for example. To manufacturing a silicon surface with pyramidal texture for solar cells it is suggested that a percentage of isopropanol contained in an etching solution is greater than a percentage of ethylenglycol. With this, a specified pyramidal size distribution is to be adjustable within a certain scattering.

However, in actual practice, it has been shown that, using one and the same etching solution, different pyramidal size distributions result depending on the quality of the silicon surface to be processed. To obtain a uniform pyramidal size distribution, it is necessary in actual practice to adapt the formula of the etching solution to the quality of the respective silicon surface to be processed. In addition to a change in the formula, the etching duration and the temperature may also have to be varied. The setting of suitable parameters to make a desired pyramidal size distribution is sometimes tedious and expensive.

A further disadvantage of conventional methods for the making of a pyramidal texture on a silicon surface is that impurities adhering to the surface of the silicon cause undesired changes in texture.

Such changes in texture lead to a silicon surface which appears visually irregular. Such a silicon surface is considered faulty.

To counteract the ,previously stated disadvantages, it is also known in accordance with prior art that a further etching step can be inserted in front of the step of treatment with an alkaline etching solution which is required for the making of the pyramidal texture. In this connection, the sawn silicon wafer is first etched with a highly concentrated alkaline solution. Such a further etching step inserted in front requires additional work. Apart from that, this cannot always fully compensate for the differences in the quality of the sawn silicon wafers.

A further possibility is to perform the further etching step using oxidizing acids. Such a further etching step also causes additional work. Apart from that, this cannot always compensate sufficiently for the different qualities of the sawn silicon wafers. Another disadvantage is that in this case highly concentrated oxidizing acids must be used and their handling is dangerous.

The object of the present invention is to eliminate the disadvantages in accordance with prior art. In particular, a method of manufacturing a silicon surface with pyramidal texture is to be specified which can be executed as simply and inexpensively as possible. In accordance with a further goal of the invention, this is to be used so that silicon surfaces can be made with a specified pyramidal texture regardless of the quality of the silicon wafers and without changing the composition and/or concentration of the etching solution.

This object is solved by the features of claim 1. Useful embodiments of the invention result from the features of claims 2 to 14.

According to the provisions of the invention, the silicon surface is treated with ozone before coming in contract with the etching solution during a method of manufacturing a silicon surface with pyramidal texture. Silicon surfaces treated in such a manner exhibit a particularly homogenous pyramidal texture even with a different quality after a subsequent treatment with an etching solution. In other words, the pyramids manufactured on the silicon surface in such a manner have a relatively narrow size distribution. In particular it is not necessary to change a composition of the etching solution or further parameters such as the temperature or the etching duration based on the quality of the silicon wafers to be treated. The suggested method can be executed simply and inexpensively.

The term “quality” is understood to mean in particular a chemical surface character of the silicon wafers. The different chemical surface character of the silicon wafer is caused by the use of different liquids used during sawing. For example, liquids such as oil or also glycol can be used. Depending on the type of liquid which is used, the sawn silicon wafers are cleaned afterwards in different ways. The silicon surface can thus particularly differ in its quality depending on whether it is hydrophobic or hydrophilic, or whether residues of the preceding cleaning step adhere to it.

In a particularly advantageous arrangement, the silicon surface is treated in the gas phase with ozone. Such a treatment step can be executed quickly and simply. Subsequent drying of the silicon surface is not necessary. It has proven to be advantageous here that the ozone concentration is greater than 20 g/m³ in the gas phase. The gas phase can usefully have a humidity of 60 to 95%, preferably 75 to 85%.

In an alternate embodiment, however, it is also possible, for the treatment with ozone, to dip the silicon wafer into de-ionized water to which ozone in a concentration of more than 1 ppm, preferably 3 to 50 ppm, is added.

Regardless of whether the silicon surface is subjected to a gas phase containing ozone or a liquid containing ozone, it has proven to be advantageous to perform the treatment at a temperature in the range from 15° C. to 60° C., preferably 20° C. to 40° C. The treatment is usefully performed for a time period from 15 seconds to 60 minutes, preferably 3 to 40 minutes. In general, it has been shown that a treatment duration in the range from 3 to 10 minutes already produces very good results.

In a further advantageous embodiment, the treatment provided by the invention with ozone is performed after manufacturing the silicon wafers via sawing. In this connection, the silicon wafers are cut in the conventional manner parallel to the <100> surface. The silicon wafers made by sawing can be wet-cleaned before the treatment with ozone provided by the invention. This step is used to remove any sawing residues left on the silicon surface. In this case, the treatment with ozone occurs after the wet-cleaning. But it is also conceivable to combine the aforementioned wet-cleaning step with the treatment step with ozone provided by the invention. In this case, the wet-cleaning would thus be done with a watery liquid to which ozone is added.

The silicon wafers treated with ozone can then be dried and packaged. In other words, they represent a ready-to-sell intermediate product which can be treated with the etching solution later at the customer's to meet the specific requirements of making the pyramidal texture.

On the other hand, it can happen in many cases, however, that the treatment step with ozone as provided by the invention is executed together with the etching step starting with delivered silicon wafers in a continuous, quasi continuous or in a batch procedure. In this connection, there can be provided in an etching and cleaning line up current from a basin to contain the etching solution a further basin to contain the de-ionized water containing ozone. As an alternative to this, a container which can also be closed with a cover, for example, can be provided in which the silicon wafers can be brought into contact with a gas phase containing ozone. In addition, it is possible, for example, to subject the silicon surfaces to be treated to ozone and water vapor or to blow them with water vapor containing ozone.

The silicon wafers treated in such a manner with ozone are subsequently dipped conventionally into an alkaline etching solution, for example. In this connection, the etching solution can contain KOH or NaOH as a component. Moreover, one or more alcohols, preferably isopropanol, can be added to the etching solution. The temperature of the etching solution is usefully in the range from 70° C. to 90° C. The etching time is in the range from 5 minutes to 20 minutes depending on the desired size of the pyramids to be made on the silicon surface.

Explanatory examples will now be discussed in more detail:

### EXAMPLE 1

A carrier holding 100 silicon wafers is placed in a container. The container is closed with a cover. Afterwards a humidity is set to a value in the range of 85 to 95% relative humidity in the container by introducing water vapor. As an alternative, the water vapor can also be created in the container. Moreover, an ozone concentration of 20 to 40 g/m³ is set in the container by adding ozone. The silicon wafers are subjected to the aforementioned gas phase for approximately 15 minutes. The interior of the container is then bathed in nitrogen or oxygen. The cover is opened and the silicon wafers contained in the carrier are then—without further intermediate steps—dipped into an etching solution to manufacture the pyramidal texture.

### EXAMPLE 2

A carrier containing 100 silicon wafers is submerged in a basin which is filled with de-ionized water. Ozone in a concentration of approximately 10 ppm is added to the de-ionized water. The temperature of the water is 25° C. to 30° C. After a treatment duration of 10 minutes, the carrier is lifted out of the treatment bath and—without further intermediate steps—dipped into an etching solution to manufacture a pyramidal texture.

1. Method for manufacturing of a silicon surface with pyramidal texture during which a silicon wafer having the silicon surface is dipped into an etching solution
characterized in that the silicon surface is treated with ozone before being brought into contact with the etching solution.

2. Method as defined in claim 1, wherein the silicon surface is treated in the gas phase with ozone.

3. Method as defined in claim 1, wherein the ozone concentration is >20 g/m³ in the gas phase.

4. Method as defined in claim 1, wherein the gas phase has an air humidity of 60 to 95%, preferably 75 to 85%.

5. Method as defined in claim 1, wherein, for the treatment with ozone, the silicon wafer is dipped into de-ionized water to which ozone in a concentration of more than 1 ppm, preferably 3 to 50 ppm, has been added.

6. Method as defined in claim 1, wherein the treatment is performed at a temperature in the range from 15° C. to 60° C., preferably 20° C. to 40° C.

7. Method as defined in claim 1, wherein the treatment is performed for a time duration of 15 seconds to 60 minutes, preferably 3 to 40 minutes.

8. Method as defined in claim 1, wherein the treatment is performed with ozone after the making of the silicon wafers by sawing.

9. Method as defined in claim 1, wherein the silicon wafers are wet-cleaned after the sawing.

10. Method as defined in claim 1, wherein the treatment with ozone is performed after the wet-cleaning.

11. Method as defined in claim 1, wherein the silicon wafers which were treated with ozone are dried and packaged.

12. Method as defined in claim 1, wherein the etching solution is an alkaline etching solution.

13. Method as defined in claim 1, wherein the etching solution contains KOH or NaOH as the main component.

14. Method as defined in claim 1, wherein the etching solution contains alcohol, preferably isopropanol.
